(19) United States
(12) Patent Application Publication
(10) Pub. No.: US 2011/0014861 A1
(43) Pub. Date: Jan. 20, 2011

(54) AIR DUCT ASSEMBLY AND HEAT DISSIPATING ASSEMBLY

(75) Inventors: LUNG-SHENG TSAI, Tu-Cheng (TW); CHIA-KANG WU, Tu-Cheng (TW); LI-PING CHEN, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/609,212

(22) Filed: Oct. 30, 2009

(30) Foreign Application Priority Data
Jul. 20, 2009 (CN) 200910304550.1

(51) Int. Cl. H05K 5/02

(52) U.S. Cl. 454/184

(57) ABSTRACT

An air duct assembly configured for helping an electronic device to dissipate heat is provided. The air duct assembly includes a left duct, right duct spaced with the left duct, and a middle duct located between the left duct and the right duct. The left and right ducts are detachably coupled to opposite sides of the middle duct. The left duct, the middle duct, and the right duct cooperatively define an airflow passage configured for directing air flowing through to the electronic device.

### BACKGROUND

1. Technical Field

The present disclosure relates to air duct assemblies and heat dissipating assemblies, particularly, to a detachable air duct assembly and a heat dissipating assembly having a detachable air duct.

2. Description of Related Art

Air duct is popularly used for facilitating heat dissipation of electronic components of a computer system. The air duct covers on the electronic components of the computer system to guide airflow from fans to the electronic components. For a large sized computer system, such as a server system, which has a great number of electronic components, a large sized air duct is needed to carry out a massive amount of heat dissipation of electronic components. When some of the electronic components in the computer system need to be replaced or repaired, the whole air duct must be correspondingly removed. Such process is inconvenient and time consuming.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled view of an air duct assembly in accordance with an embodiment.

FIG. 2 is an isometric view of the air duct assembly of FIG. 1.

FIG. 3 is an exploded, isometric view of the air duct assembly of FIG. 2.

FIG. 4 is an assembly view of FIG. 1.

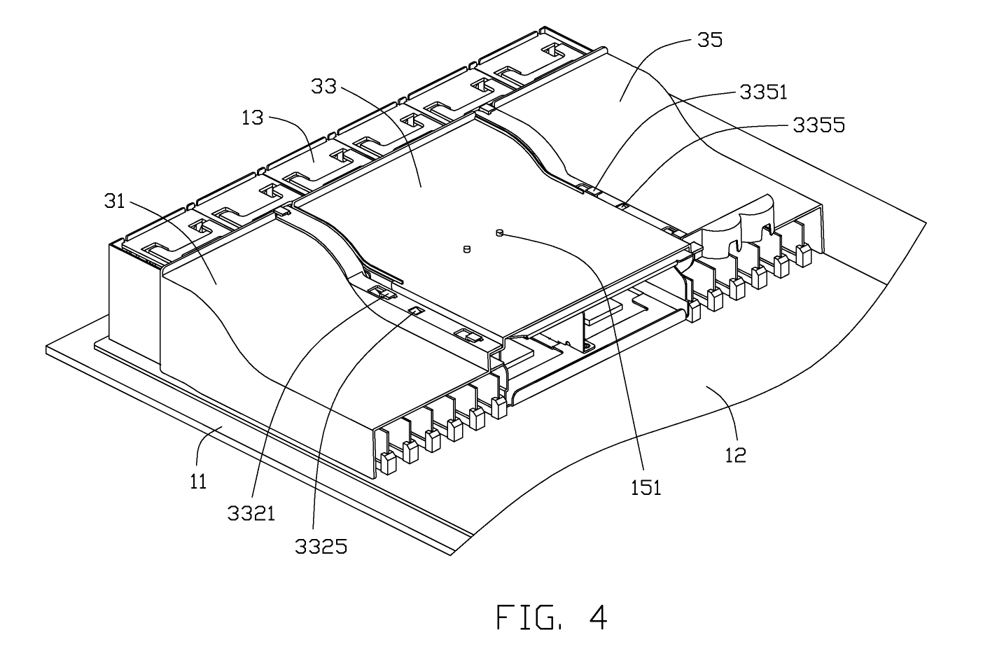

FIG. 5 is similar to FIG. 4, but showing two ducts removed from the electronic device.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

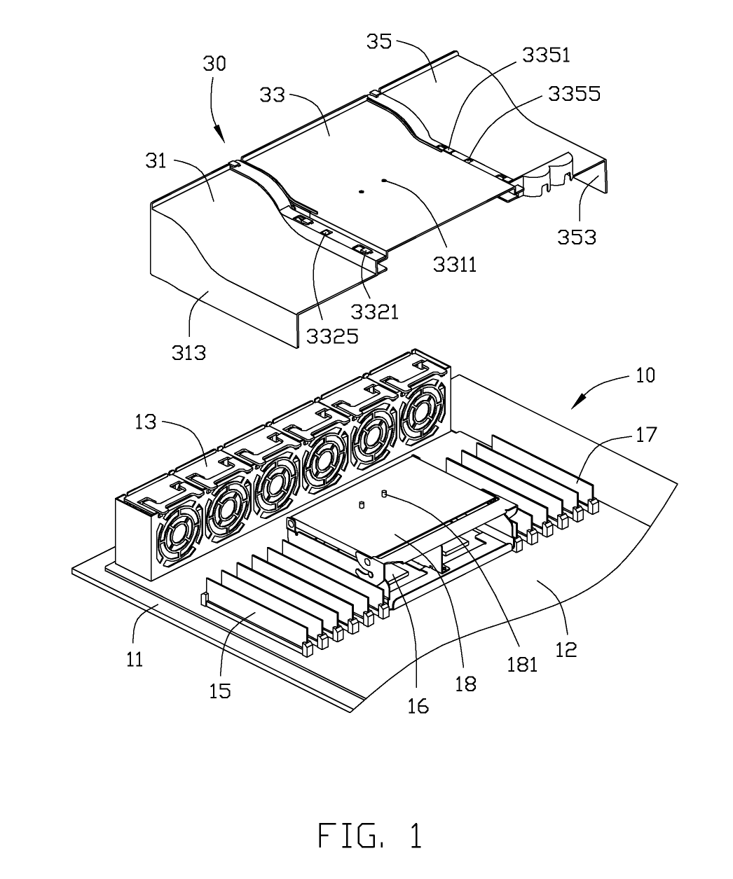

Referring to FIG. 1, a heat dissipating assembly 50 of an embodiment includes an electronic device 10 and an air duct assembly 30 configured for dissipate heat from the electronic device 10. The electronic device 10 includes a chassis 11 (only a bottom wall is shown), a circuit board 12 disposed in the chassis 11, and a plurality of fans 13. A first group of electronic components (such as memories) 15, a second group of electronic components (such as CPU chips) 16, and a third group of electronic components 17 are arranged on the circuit board 12. The first group of electronic components 15 and the third group of electronic components 17 are located at opposite sides of the second group of electronic components 16. A securing bracket 18 is disposed above the CPU chips 16 to mount a heat dissipating device (not shown) for the CPU chips 16 to the circuit board 12. Two securing posts 181 protrude from a top wall of the securing bracket 18.

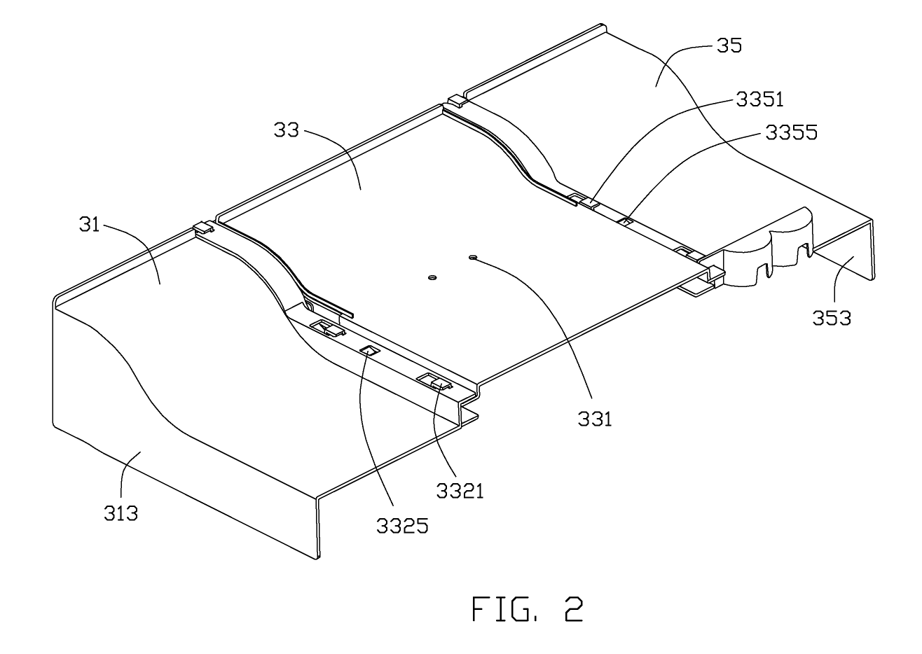

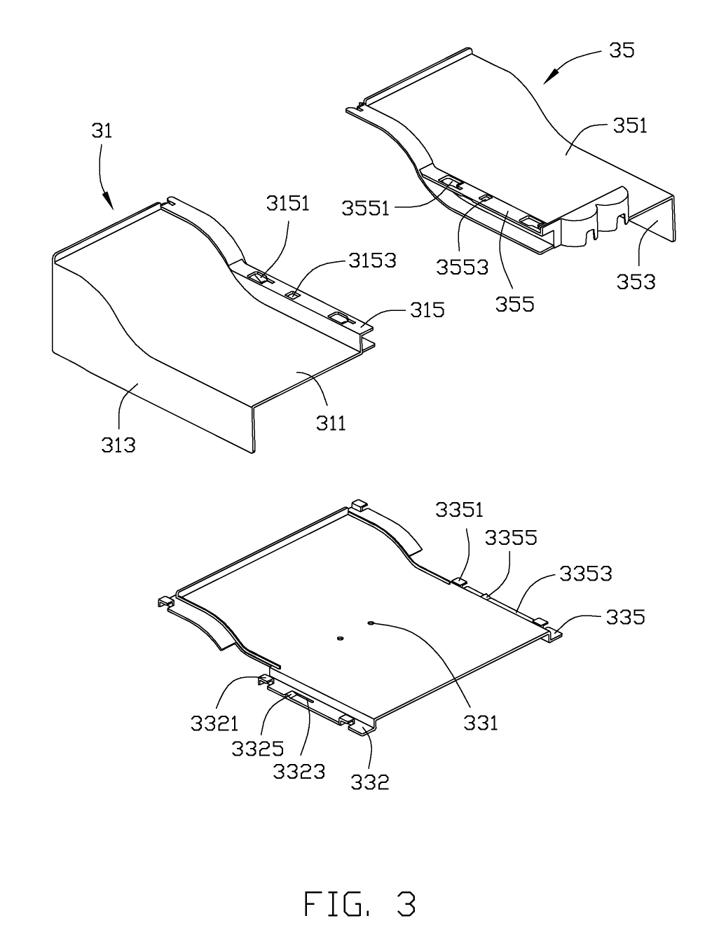

Referring also to FIGS. 2 and 3, the air duct assembly 30 includes a left duct 31, a middle duct 33, and a right duct 35 capable of being separated from each other. The left duct 31 and the right duct 35 are coupled to opposite sides of the middle duct 33.

The middle duct 33 defines two securing apertures 331 corresponding to the securing posts 181 of the securing bracket 18. A first bent flange 332 and a second bent flange 335 extend from opposite sides of the middle duct 33. The first bent flange 332 forms a plurality of first securing blocks 3321 and a first elastic clip 3323. The first elastic clip 3323 protrudes a first wedge-shaped blocking protrusion 3325 at a free end thereof. The second bent flange 335 forms a plurality of second securing blocks 3351 and a second elastic clip 3353. The second elastic clip 3353 protrudes a second wedge-shaped blocking protrusion 3355 at a free end thereof.

The left duct 31 includes a first top wall 311 and a first sidewall 313 generally perpendicular to the first top wall 311. The first top wall 311 extends a first connecting plate 315. The first connecting plate 315 defines a plurality of first securing slots 3151 corresponding to the first securing blocks 3321, and a securing opening 3153 corresponding to the first elastic clip 3323.

The right duct 35 includes a third top wall 351 and a third sidewall 353. The third top wall 351 extends a third connecting plate 355. The third connecting plate 355 defines a plurality of third securing slots 3551 corresponding to the second securing blocks 3351, and a third securing opening 3553 corresponding to the second elastic clip 3353. The first top wall 311 of the left duct 31, the middle duct 33, and the third top wall 351 of the right duct 35 have substantially same profiles, which cooperatively defines a smooth guiding passage for the air duct.

In assembly, the first securing blocks 3321 and the second securing blocks 3351 of the middle duct 33 respectively engage the first securing slot 3151 of the left duct 31 and the third securing slot 3551 of the right duct 35. The left duct 51 and the right duct 55 are moved relative to the middle duct, so that the first blocking protrusion 3325 of the first elastic clip 3323 and the second blocking protrusion 3355 of the second elastic clip 3353 engage in the first securing opening 3153 and the third securing opening 3553. Thus, the air duct assembly 30 is assembled. The first top wall 31, the middle duct 33, and the third top wall 35 are connected in series to act as a top wall of the air duct assembly 30. The first sidewall 313 of the left duct 31 and the third sidewall 353 of the right duct 35 act as two sidewalls of the air duct assembly 30. The top wall and the two sidewalls of the air duct assembly 30 cooperatively define an air flow passage to help the electronic components dissipate heat.

In use, the air duct assembly 30 is disposed on the circuit board 12 and accommodates the first group of electronic components 15, the second group of electronic components 16, and the third group of electronic components 17. The securing posts 181 of the securing bracket 18 extend through the securing holes 3311 in the middle duct 33, so as to secure the middle duct 33 to the securing bracket 18. Thus, the air duct assembly 30 is mounted in the chassis 11. The airflow passage is aligned with the plurality of fans 13. The left duct 31 correspondingly located above the first group of electronic components 15, the middle duct 33 correspondingly located above the second group of electronic components 16, and the right duct 35 correspondingly located above the third group of electronic components 17, so as to help the electronic components dissipate heat.

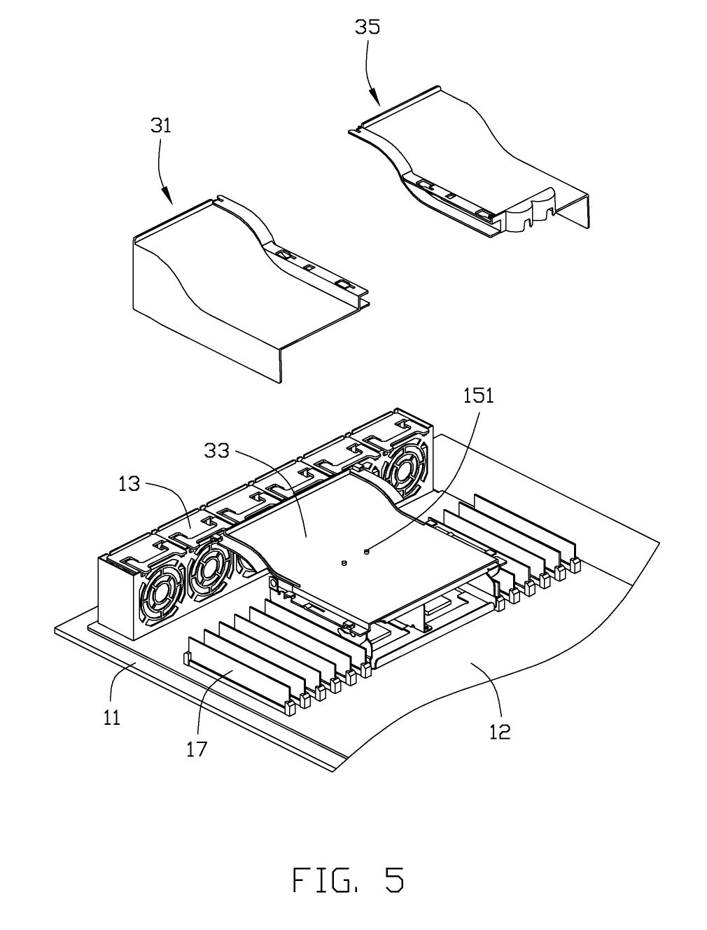

Referring to FIG. 5, during replacement of the corresponding electronic components 16 and 18, the air duct 31 and/or 35 is moved relative to the middle duct 33. The first elastic securing clip 3323 and/or the second elastic securing clip 3353 are/is deflected so as the first blocking protrusion 3325 and/or the second blocking protrusion 3355 are/is disengaged from the first securing opening 3153 and/or the third securing opening 3553. Thus, the left duct 31 and/or the right duct 35 are/is disassembled from the middle duct 33. The corresponding electronic components 16 and 18 may be replaced.

According to the above description, the air duct assembly 30 is used for dissipating heat for a large amount of electronic components. When some of the components are needed to be replaced or repaired, the duct corresponding to the components is disassembled from the air duct assembly 30. It is not necessary to detach the whole air duct assembly 30 from the electronic device 10.

It is to be understood, however, that even though numerous characteristics and advantages of the embodiments have been set forth in the foregoing description, together with details of the structure and function of the present disclosure, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. An air duct assembly configured for helping an electronic device to dissipate heat, comprising:
a left duct;
a right duct spaced with the left duct; and
a middle duct located between the left duct and the right duct, and the left and right ducts are detachably coupled to opposite sides of the middle duct; wherein
the left duct, the middle duct, and the right duct cooperatively define an airflow passage configured for directing air flowing through to the electronic device.

2. The air duct assembly of claim 1, wherein the left duct comprises a first top wall and a first sidewall connected to the first top, and the right duct comprises a third top wall and a third sidewall connected to the third top wall, the airflow passage is surrounded by the first top wall, the middle duct, and the third top wall.

3. The air duct assembly of claim 1, wherein a left side of the middle duct forms a first securing block and a first elastic clip, the left duct defines a first securing slot and a first securing hole, the first securing block engages in the first securing slot to limit the left duct to move along a first direction relative to the middle duct, and the first elastic clip engages in the first securing hole to limit the left duct to move along a second direction relative to the middle duct.

4. The air duct assembly of claim 3, wherein the first direction is perpendicular to the second direction.

5. The air duct assembly of claim 3, wherein the other side of the middle duct forms a second securing block and a second elastic clip; the right duct defines a second securing slot and a second securing hole; the second securing block engages in the second securing slot to limit the right duct to move along a third direction relative to the middle duct, and the second elastic clip engages in the second securing hole to limit the middle duct to move along a fourth direction relative to the middle duct.

6. The air duct assembly of claim 5, wherein the third direction is perpendicular to the fourth direction.

7. The air duct assembly of claim 2, wherein the first top wall of the left duct, the middle duct, and the third top wall of the right duct have substantially same profiles and cooperatively defines a smooth guiding passage for the air duct.

8. A heat dissipating assembly, comprising:
a chassis having a first group of electronic components, a second group of electronic components, and a third group of electronic components disposed therein; and
an air duct located in the chassis, the air duct comprising:
a middle duct corresponding to the second group of electronic device;
a left duct corresponding to the first group of electronic device, the left duct is detachably coupled to one side of the middle duct; and
a right duct corresponding to the third group of electronic device, the right duct is detachably coupled to the other side of the middle duct;
wherein the left duct, the middle duct, and the right duct cooperatively define an airflow passage to accommodate the first group, second group, and third group of electronic components.

9. The heat dissipating assembly of claim 8, wherein the left duct comprises a first top wall and a first sidewall connected to the first top, the right duct comprises a third top wall and a third sidewall connected to the third top wall, and the airflow passage is surrounded by the first top wall, the middle duct, and the third top wall.

10. The heat dissipating assembly of claim 9, wherein one side of the middle duct forms a first securing block and a first elastic clip, the left duct defines a first securing slot and a first securing hole, the first securing block engages in the first securing slot to limit the left duct to move along a first direction relative to the middle duct, and the first elastic clip engages in the first securing hole to limit the left duct to move along a second direction relative to the middle duct.

11. The heat dissipating assembly of claim 10, wherein the first direction is perpendicular to the second direction.

12. The heat dissipating assembly of claim 10, wherein the other side of the middle duct forms a second securing block and a second elastic clip, the right duct defines a second securing slot and a second securing hole, the second securing block engages in the second securing slot to limit the right duct to move along a third direction relative to the middle duct, and the second elastic clip engages in the second securing hole to limit the middle duct to move along a fourth direction relative to the middle duct.

13. The heat dissipating assembly of claim 12, wherein the third direction is perpendicular to the fourth direction.

14. The heat dissipating assembly of claim 9, wherein the first top wall of the left duct, the middle duct, and the third top wall of the right duct have substantially same profiles and cooperatively define a smooth guiding passage for the air duct.

15. The heat dissipating assembly of claim 8, wherein a plurality of fans are disposed in the chassis and are located adjacent to the first group, second group, and third group of electronic components, the air duct airflow passage is aligned with the fans.

16. The heat dissipating assembly of claim 8, wherein the heat dissipating assembly further comprises a securing bracket accommodating the second group of electronic components, two securing posts extend from a top of the securing bracket, and the middle duct defines two corresponding securing apertures; and the securing posts engage the securing apertures to position the middle duct on the securing bracket.
